(19) United States
(12) Patent Application Publication
(10) Pub. No.: US 2003/0235243 A1
(43) Pub. Date: Dec. 25, 2003

(54) Method for windowed noise auto-correlation

(76) Inventor: Shousheng He, Sodra Sandby (SE)

Correspondence Address: JENKENS & GILCHRIST, P.C., 1445 Ross Avenue, Suite 3200, Dallas, TX, 75202-2799, US

(21) Appl. No.: 10/180,837

(22) Filed: Jun. 25, 2002

(51) Int. Cl. H03K 5/159; H03H 7/30; H03H 7/40

(52) U.S. Cl. 375/231; 375/229

(57) ABSTRACT

A method for estimating noise auto-correlation for an equalizer includes the step of estimating a noise auto-correlation and weighting the estimated noise auto-correlation by a selected weighted window.

### TECHNICAL FIELD

This invention relates to equalizers, and more particularly, to a method for using a one-side window for weighting noise auto-correlation estimates in an equalizer.

### BACKGROUND OF THE INVENTION

Equalizers are utilized for baseband processing in wireless communication systems. Some equalizers require an estimation of the noise auto-correlation for equalizer settings and other parameter estimates. When the interference/noise of a wireless digital communication system does not comprise white noise and includes, for example, co-channel and/or adjacent channel interference, knowledge of the character of the noise is essential to the performance of the equalizer Optimal performance of the equalizer requires an unbiased channel estimation, an unbiased frequency offset estimation and unbiased whitening filter settings. However, since the noise character of a provided signal is usually not known, an estimation of the noise auto-correlation must be performed. The quality of this estimation affects the performance of the equalizer.

The performance of an equalizer based upon the noise auto-correlation calculated according to existing methods has been shown to degrade in certain channel conditions such as high signal to noise ratio (SNR). Within existing methods, different auto-correlation elements of the calculated auto-correlation have different qualities. Due to the limited lengths of a training sequence used to calculate the noise auto-correlation, the quality of the noise auto-correlation elements decrease with the offset The last few elements are not very reliable due to the small number of product terms of the noise components being used. This unreliability introduces a distortion that significantly degrades the performance of the equalizer when later elements of the estimated auto-correlation are used.

### SUMMARY OF THE INVENTION

The present invention overcomes the foregoing and other problem with a method for estimating a noise auto-correlation for an equalizer wherein an initial estimated noise auto-correlation is first established, and a weighted window is selected to decrease unreliable elements of the noise auto-correlation. The estimated noise auto-correlation is weighted by the weighted window by multiplying the noise auto-correlation by the weighted window.

### BRIEF DESCRIPTION OF THE DRAWINGS

A more complete understanding of the method and apparatus of the present invention may be obtained by reference to the following Detailed Description when taken in conjunction with the accompanying Drawings wherein:

FIG. 1 is a block diagram of a portion of an estimation based automatic frequency correction (AFC) receiver,

FIG. 2 is a flow diagram illustrating the method of the present invention; and

FIG. 3 illustrates the performance of an equalizer using windowed noise auto-correlation with respect to an equalizer using a phase locked loop approach.

### DETAILED DESCRIPTION

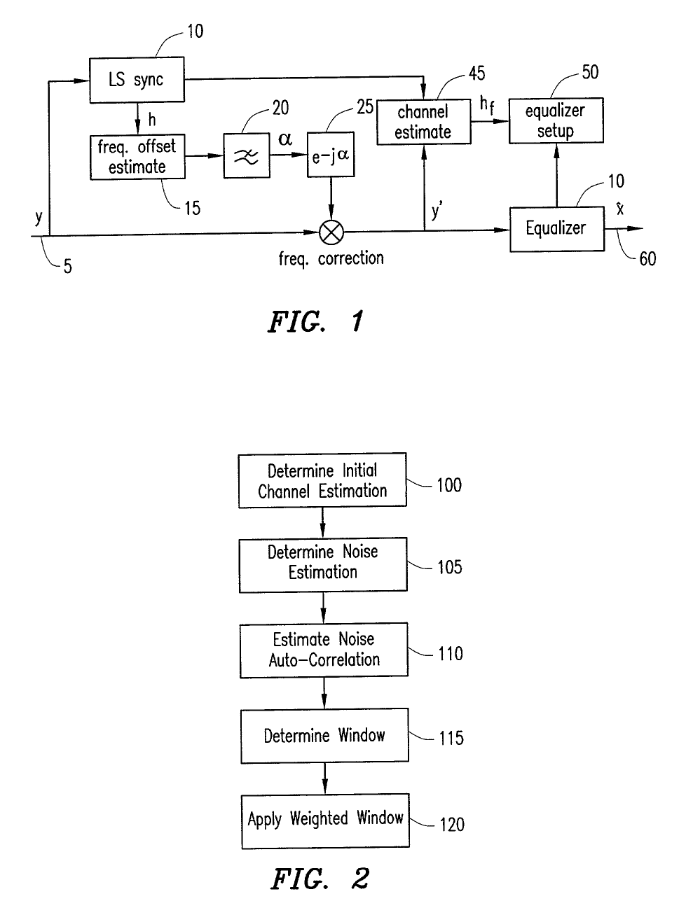

Referring now to the drawings, and more particularly to FIG. 1, there is illustrated a block diagram of a portion of an estimation based automatic frequency correction (AFC) receiver according to the present invention. A received signal γ is applied to an input 5. The received signal γ has an accurate burst synchronization achieved using an efficient least squares estimation approach at 10. This enables an initial determination of the channel span, an initial estimation of the channel taps and a noise estimate to be obtained. The incremental phase offset corresponding to the frequency offset α is estimated at 15 assuming knowledge of the channel noise characteristics. The frequency offset α is smoothed at 20, 25 by a simple low-pass filter to remove glitches from the estimation. Frequency offset is corrected at 30 by incrementally derotating the received signal γ with α. The frequency corrected signal γ′ is provided to the equalizer 40 and channel estimate block 45. Channel estimate block 45 generates a channel estimate which is applied to the equalizer set up 50. The equalizer set up 50 determines a number of parameters required by the equalizer 40 including an estimated noise auto-correlation. Using the frequency corrected signal γ′ and the parameters generated by the equalizer set up 50, the equalizer 40 generates the equalized output signal \hat{x} at control 60.

Referring now to FIG. 2, there is illustrated a method for generating a windowed noise auto correlation within the equalizer set up 50 of a TDMA receiver used in, for example, a GSM/EDGE systems. A training sequence of limited length N is transmitted together with a data sequence for the estimation of a multi-path (M-tap) channel. The training sequence is embedded in the received signal. A windowed estimation of noise auto-correlation is obtained by first determining at 100 an initial channel estimation using white noise according to the equation:

ĥ=(T^{H}T)⁻¹T^{H}γ (1)

where T is the matrix of the training sequence, and r is the received signal of N−M+1 symbols. A noise estimation at 105 is determined by taking the difference between the received signal r and a predicted signal \hat{r} according to the equation.

\hat{n}=r−\hat{r}=r−Tĥ (2)

Estimation of the noise auto-correlation function from the noise estimation will then be determined at 110 according to the equation:

$${ρ}_{k} = \frac{1}{N - M + 1} {\sum }_{j = 0}^{N - M + 1 - k} {\hat{n}}_{j} * {\hat{n}}_{j + k} \qquad ( 3 )$$

where * indicates complex conjugation.

Simulations of the performance of an equalizer based upon the noise auto-correlation calculated using equation (3) shows degradation within channel conditions such as high signal to noise ratio. A close examination of equation (3) reveals that different auto-correlation elements are of different quality. All the auto-correlation elements have to be calculated from product terms \hat{n}ⱼ*\hat{n}ⱼ₊ₖ of N−M+1 noise components. The first element ρₒ using N−M+1 terms \hat{n}ⱼ*\hat{n}ⱼ, the second element ρ₁ using N−M terms \hat{n}ⱼ*\hat{n}ⱼ₊₁, and so on. The last element ρ_{N-M+1} uses only one term \hat{n}₀*\hat{n}_{N-M+1}. Thus, due to the limited length of the training sequence, the quality of the noise auto-correlation elements decreases with the offset. The last few elements are not very reliable due to the use of too few product terms of the noise components. This unreliability introduces a distortion that can significantly degrade the equalizer performance when later elements of the estimated auto-correlation must be used.

This problem may be overcome by applying a weighting window at step 120 to the estimated noise auto-correlation determined at step 115 according to the equation:

φₖ=ρₖwₖ (4)

The window wₖ is chosen in such a way as to decrease the importance of the unreliable elements in the estimation while retaining the positive definite property of the noise auto-correlation matrix.

In one embodiment, a practical choice can be a one-side Hanning (raise cosine) window:

$${w}_{k} = \frac{1}{2} ( cos ( \frac{k π}{N - M + 1} ) + 1 ) , k = 0 , … , N - M + 1 \qquad ( 5 )$$

The use of the one-side Hanning window is merely meant for purposes of illustration and it should be realized that any window chosen to decrease the importance of unreliable elements in the estimation while maintaining the positive properties of the noise auto-correlation matrix would be applicable. Other possible window forms include a Hamming or Blackman window as disclosed in “Discrete-time Signal Processing”, A. V. Oppenheim and R. W. Schafer, Prentice Hall 1989 which is incorporated herein by reference.

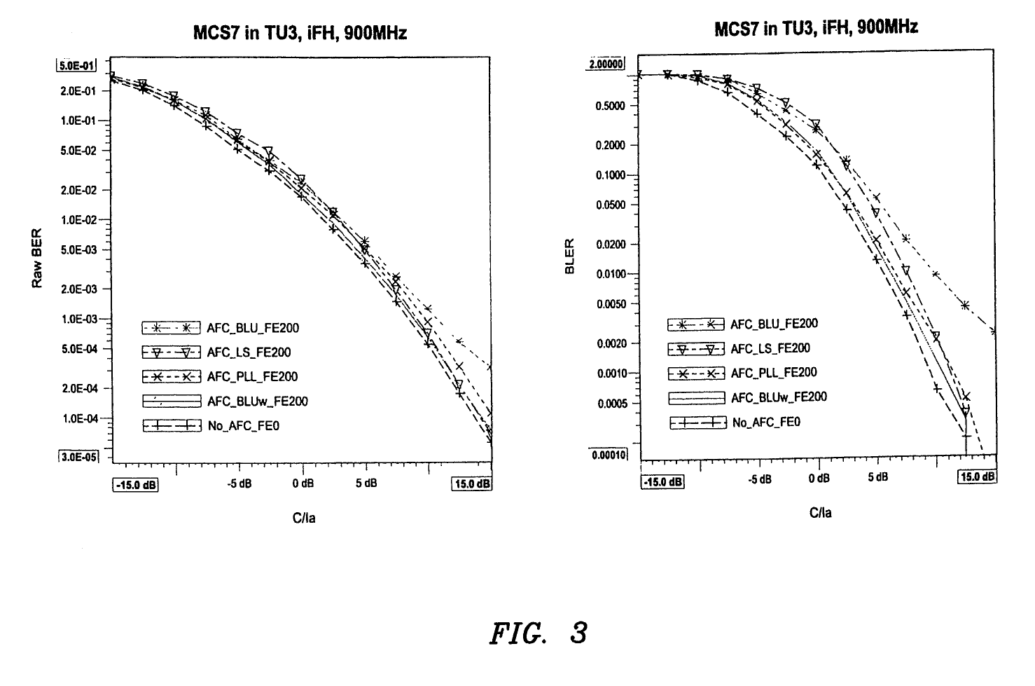

Adding a one-side window to the noise auto-correlation has been proven to be a simple and effective manner to improve performance of an equalizer. Simulation results such as those illustrated in FIG. 3 demonstrate the performance of a AFC receiver using windowed noise auto-correlation comparing favorably to an equalizer using a phase locked loop approach.

The previous description is of a preferred embodiment for implementing the invention, and the scope of the invention should not necessarily be limited by this description. The scope of the present invention is instead defined by the following claims.

What is claimed is:

1. A method for estimating noise auto-correlation for setting up of an equalizer, comprising the steps of:
estimating a noise auto-correlation;
selecting a weighted window; and
weighting the estimated noise auto-correlation by the weighted window.

2. The method of claim 1, wherein the weighted window is selected to decrease unreliable elements of the estimated noise auto-correlation.

3. The method of claim 1, wherein the weighted window comprises a one-side Hanning window.

4 The method of claim 1, wherein the step of selecting further comprises selecting the weighted window according to the equation:
$${w}_{k} = \frac{1}{2} ( cos ( \frac{k π}{N - M + 1} ) + 1 ) , k = 0 , … , N - M + 1.$$
k=0, . . . , N−M+1.

5 The method of claim 1, wherein the step of weighting further comprises the step of multiplying the estimated noise auto-correlation by the weighted window.

6. The method of claim 1, wherein the step of estimating further comprises the steps of:
estimating an initial channel responsive to a received signal and a matrix of a training sequence;
determining a noise estimate responsive to the received signal, the matrix of the training sequence, and the initial channel estimation, and estimating the noise auto-correlation responsive to the noise estimation.

7. A method for estimating noise auto-correlation for an equalizer, comprising the steps of
estimating an initial channel responsive to a received signal and a matrix of a training sequence;
determining a noise estimate responsive to the received signal, the matrix of the training sequence, and the initial channel estimation;
estimating a noise auto-correlation responsive to the noise estimation;
selecting a weighted window to decrease unreliable elements of the estimated noise auto-correlation; and
weighting the estimated noise auto-correlation by the weighted window by multiplying the estimated noise and auto correlation by the weighted window.

8. The method of claim 1, wherein the weighted window comprises a one-side Hanning window.

9. The method of claim 1, wherein the step of selecting further comprises selecting the weighted window according to the equation
$${w}_{k} = \frac{1}{2} ( cos ( \frac{k π}{N - M + 1} ) + 1 ) , k = 0 , … , N - M + 1$$
k=0, . . . , N−M+1

10 An equalizer, comprising:
an input for a received signal;
an output for an equalized signal, and
first circuitry connected to the input and the output and configured to
estimate a noise auto-correlation,
select a weighted window; and
weight the estimated noise auto-correlation by the weighted window.

11. The equalizer of claim 10, wherein the weighted window is selected to decrease unreliable elements of the estimated noise auto-correlation.

12 The equalizer of claim 10, wherein the weighted window comprises a one-side Hanning window.

13. The equalizer of claim 10, wherein the weighted window is selected according to the equation.
$${w}_{k} = \frac{1}{2} ( cos ( \frac{k π}{N - M + 1} ) + 1 ) , k = 0 , … , N - M + 1$$
k=0, . . . , N−M+1

14. The equalizer of claim 10, wherein the first circuitry is further configured to multiply the estimated noise auto-correlation by the weighted window.

15. The method of claim 1, wherein the first circuitry is further configured to:
estimate an initial channel responsive to the received signal and a matrix of a training sequence;
determine a noise estimate responsive to the received signal, the matrix of the training sequence, and the initial channel estimation, and
estimate the noise auto-correlation responsive to the noise estimation.
